(19) United States
(12) Patent Application Publication
(10) Pub. No.: US 2006/0225657 A1
(43) Pub. Date: Oct. 12, 2006

(54) Apparatus and method for depositing a dielectric film

(76) Inventors: Ichiro Mizushima, Yokohama-shi (JP); Kyoichi Suguro, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/304,653

(22) Filed: Dec. 16, 2005

(30) Foreign Application Priority Data
Apr. 7, 2005 (JP) P2005-111182

(51) Int. Cl. C23C 16/00; H01L 21/20

(52) U.S. Cl. 118/724; 427/248.1; 438/584

(57) ABSTRACT

An apparatus for depositing a dielectric film includes a first gas introduction line introducing and disconnect a first gas including a compound containing a constituent element of the dielectric film, to a surface of a substrate stored in a reaction chamber, and a second gas introduction line introducing and disconnect a second gas containing one of an oxidizing agent, a reducing agent, and a nitriding agent, to the surface of the substrate. A heating source repeatedly irradiates a pulsed energy having a pulse width of about 0.1 ms to about 100 ms on the substrate. An evacuation system evacuates the first and second gases from the reaction chamber. A control system sequentially and repeatedly executes a cycle including operations of introducing the first gas, introducing the second gas, and irradiating the energy.

### CROSS REFERENCE TO RELATED APPLICATIONS AND INCORPORATION BY REFERENCE

This application is based upon and claims the benefit of priority from prior Japanese Patent Application P2005-111182 filed on Apr. 7, 2005; the entire contents of which are incorporated by reference herein.

### BACKGROUND OF THE INVENTION

1. Field of the Invention

The present invention relates to an apparatus and a method for depositing a thin dielectric film, such as an oxide film or a nitride film. More specifically, the present invention relates to an apparatus and a method for depositing a dielectric film onto a surface of a semiconductor substrate having an impurity diffusion layer, so as to manufacture a semiconductor device.

2. Description of the Related Art

Large scale integrated (LSI) circuits have been seeing increases in the degree of integration to improve their performance, and at the same time, micro-sized elements have been advancing more rapidly than ever. In manufacturing processes of such an LSI, a low thermal budget has become increasingly essential.

One of the approaches for achieving a low thermal budget is a reduction in process temperature. There are various processes which have to be done at a low temperature. For example, a low temperature, specifically a process temperature of about 600° C. or less, is a particular requirement for all of processes after forming a shallow impurity diffusion layer from a surface of a semiconductor substrate, as source and drain regions of a transistor. The reason is that it is necessary to achieve and maintain a supersaturated high concentration of activated dopant atoms in a diffusion layer, in order to achieve a low sheet resistance along with formation of a shallower diffusion layer.

For example, the supersaturated concentration of the dopant atoms in the diffusion layer is achieved by executing annealing such as flashlamp annealing at a high temperature in a short time, after implanting impurity ions by ion implantation and the like, in a surface layer of the semiconductor substrate. However, subsequent processes have to be implemented at a temperature of about 600° C. or less, in order to maintain the supersaturated concentration in the diffusion layer. When such low temperature processes are impossible, inactivation of the dopant atoms occurs, so as to increase sheet resistance. As a result, problem in an increase in parasitic resistance of the transistor may occur.

The processes following the formation of the diffusion layer include a deposition process of a silicon oxide (SiO₂) film or a silicon nitride (Si₃N₄) film by thermal chemical vapor deposition (thermal CVD). The deposition process has to be executed inevitably while suppressing thermal budget.

One of the approaches for depositing an oxide film or a nitride film with a low thermal budget is to reduce a process temperature. For example, a SiO₂ film is currently deposited by thermal CVD using tetraethoxysilane (TEOS) and oxygen (O₂). However, a temperature of about 600° C. is a lower limit of the process temperature of the thermal CVD using TEOS and O₂. Thus, it is difficult to implement thermal CVD using TEOS and O₂ at a temperature lower than 600° C. A Si₃N₄ film can be deposited even at about 450° C. by thermal CVD using hexachlorodisilane (HCD) and ammonia (NH₃). However, there is a problem with regard to film quality to contain a high concentration of hydrogen in the deposited Si₃N₄ film by thermal CVD using HCD and NH₃.

As a method for depositing an oxide film or a nitride film with a low thermal budget, besides lowering the process temperature, a process at a high temperature in a short time may be used. For example, deposition reaction occurs on a surface of a semiconductor substrate by irradiating a light of a flashlamp having an extremely short pulse width of several ms, to increase and decrease a surface temperature of the semiconductor substrate in a short period of time. A proposal for a process at a high-temperature in a short time is provided (see Japanese Patent Laid-Open No. Hei 10 (1998)-72283). The proposal provides an example of a method for depositing a germanium thin film including introducing a germane (GeH₄) gas into a reaction chamber as a source gas to be adsorbed on a surface of a semiconductor substrate, and decomposing adsorbed gas molecules by irradiating a pulsed light of a flashlamp. In the proposal, it is also shown that it is apparently possible to deposit a thin film by one atomic layer by irradiating a pulsed light.

Additionally, in the above-mentioned proposal, it is suggested that growth of a film of mixed crystal substance in an atomic layer regime by simultaneously introducing two or more source gases may be easily analogized. Furthermore, it is suggested that a multilayer film including different kinds of substances for every atomic layer or every plural atomic layers may be deposited by alternately introducing two or more source gases with irradiating a pulsed light one each occasion of the gas introduction.

In a case using a single gas, the above-mentioned proposal is a technology to deposit a covalent substance of a single element simply by decomposition of hydride and the like. In the suggested example in which the plural source gases are alternately used, each of different independent atomic layers is deposited from each of the source gases, and a single substance is not synthesized and deposited from the plural source gases. In the suggested example in which the plural source gases are simultaneously introduced to grow the mixed crystal substance in the atomic layer regime, it is possible to generate a single mixed crystal substance. However, controllability for a film deposition process and film quality is inferior. Specifically, the film deposition may proceed continuously due to the simultaneous introduction of the source gases, and a stoichiometric composition of the deposited film may not be determined due to an indefinite reaction ratio of the source gases. Thus, the film deposition for each single atomic layer may be difficult, unevenness of the film deposition may occur, and an undesirable side reaction may occur. Furthermore, there is no disclosure or suggestion as to what means of productivity improvement is provided as a practical thin film deposition technology using a flashlamp light source.

After all, the heretofore proposed methods and apparatuses have difficulty in depositing an oxide film or a nitride film having good film quality with a low thermal budget. Moreover, the heretofore proposed methods and apparatuses cannot be expected to achieve a practical level of productivity.

### SUMMARY OF THE INVENTION

A first aspect of the present invention inheres in an apparatus for depositing a dielectric film, including a first gas introduction line configured to introduce and disconnect a first gas to a surface of a substrate stored in a reaction chamber, the first gas including a compound containing a constituent element of the dielectric film; a second gas introduction line configured to introduce and disconnect a second gas to the surface of the substrate, the second gas containing one of an oxidizing agent, a reducing agent, and a nitriding agent; a heating source configured to repeatedly irradiate a pulsed energy on the substrate to heat the substrate, the energy having a pulse width of about 0.1 ms to about 100 ms; an evacuation system configured to evacuate the first and second gases from the reaction chamber; and a control system configured to sequentially and repeatedly execute a cycle, the cycle including operations of introducing the first gas, disconnecting the first gas, evacuating the unreacted first gas, introducing the second gas, irradiating the energy, disconnecting the second gas, and evacuating the unreacted second gas.

A second aspect of the present invention inheres in a method for depositing a dielectric film, including sequentially and repeatedly executing a plurality of cycles, each of the cycle including introducing a first gas including a compound containing a constituent element of the dielectric film, so as to adsorb reacting species on a surface of a substrate, the reacting species being molecules of the first gas or decomposed molecules of the first gas; introducing the second gas containing one of an oxidizing agent, a reducing agent, and a nitriding agent to the surface of the substrate; and irradiating a pulsed energy having a pulse width of about 0.1 ms to about 100 ms on the surface of the substrate, so as to react the second gas to the adsorbed reacting species.

### BRIEF DESCRIPTION OF THE DRAWINGS

FIG. 1 is a schematic view showing an example of a deposition apparatus according to an embodiment of the present invention.

FIGS. 2 to 4 are schematic views showing an example of the connection between the heating source and the capacitors.

FIGS. 5 to 7 are schematic views showing another example of the connection between the heating source and the capacitors.

FIG. 8 is a process flow showing an example of a method for depositing a dielectric film according to the embodiment of the present invention.

FIG. 9 is a view showing an example of the heating characteristic of the heating source of the deposition apparatus according to the embodiment of the present embodiment.

FIG. 10 is a view showing an example of the timing charts for depositing a silicon nitride film.

FIG. 11 is a graph showing an example of a relation of thickness of the deposited silicon nitride film to a number of cycles.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. Unless otherwise specified hereinafter, a “pulse width” refers to a full width at half maximum of energy intensity in a pulse waveform.

(Deposition Apparatus)

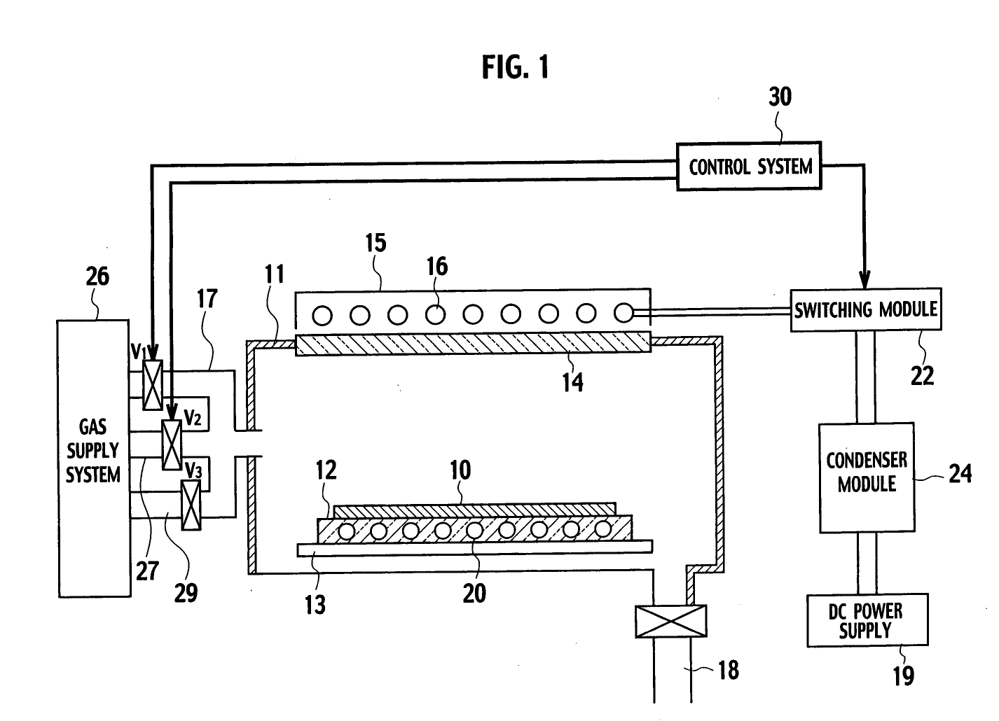

As shown in FIG. 1, an apparatus for depositing a dielectric film according to an embodiment of the present invention is used for depositing a thin dielectric film on a semiconductor substrate 10 by decomposition, chemical oxidation, reduction, or nitridation of a source gas having a compound containing a constituent element of a dielectric film to be grown, at a high temperature.

The apparatus includes a reaction chamber 11 storing a substrate 10 on which a film deposition process is implemented; a susceptor 12, on which the substrate 10 is placed, disposed on a supporting stage 13 in the reaction chamber 11; a first gas introduction line 17 including a pipe and a valve V₁, which supplies the source gas (first gas) into the reaction chamber 11; a second gas introduction line 27 including a pipe and a valve V₂, which supplies a second gas containing one of an oxidizing agent, a reducing agent, and a nitriding agent; a carrier gas introduction line 29 including a pipe and a valve V₃, which supplies a carrier gas; an evacuation system 18 including a pipe, a valve, and a vacuum pump (not shown), which evacuates the reaction chamber 11; and a heating source 16 which supplies a pulsed energy onto a surface of the substrate 10. The first gas introduction line 27, the second gas introduction line 29, and the carrier gas introduction line 29 are connected to a gas supply system 26. The gas supply system 26 includes gas sources of the first gas, the second gas, the carrier gas, and the like. A flashlamp light source, for example, is desirably used as the heating source 16. Unless otherwise specified hereinafter, the flashlamp light source will be used as the heating source 16.

The reaction chamber 11 is made of metal such as stainless steel, for example. A transparent window 14 facing the susceptor 12 and a housing 15 for accommodating the heating source 16 are disposed on top of the reaction chamber 11. The transparent window 14 is made of, for example, quartz glass. The transparent window 14 transmits the light emitted from the heating source 16 to the substrate 10. The transparent window 14 also maintains an airtight barrier separating the reaction chamber 11 from the housing 15.

Ceramics, quartz, or silicon carbide may be used for the susceptor 12. Aluminum nitride (AlN) is desirably used as the ceramics. When depositing a dielectric film, the substrate 10 is previously kept at a constant temperature by preheating. A heating source other than the heating source 16 is necessary for the preheating. In the exemplary configuration illustrated in FIG. 1, a preheating source 20 is provided inside the susceptor 12. As the susceptor 12, stainless steel, of which a surface is protected by quartz or ceramics such as AlN, may be used. As the substrate 10, a semiconductor substrate, such as Si, is used.

An embedded metallic heater such as a nichrome wire, or a heating lamp is used as the preheating source 20. Temperature of the preheating source 20 is controlled by, for example, a control system 30 placed outside the reaction chamber 11.

The heating source 16 is a light source capable of sequentially emitting pulsed light beams to irradiate an area at least several centimeters square at a time. The heating source is typically a flashlamp light source, particularly a xenon flashlamp light source. The pulse width is desirably set to about 0.1 ms to about 200 ms, and the energy density of a single pulse in an irradiation plane is desirably set to 5 J/cm² to 100 J/cm².

When implementing a plurality of irradiations of the pulsed light using the heating source 16, a shorter interval between the irradiations is more desirable in order to reduce the total time of film deposition and to improve the efficiency of gas consumption. However, the flashlamp light source can not irradiate the light until an amount of electric charge stored in a capacitor, which is fed to the flashlamp light source, attains a reference value. Therefore, for the current flashlamp light source, it is impossible to decrease an interval between irradiations and to reduce a practical process time.

In the embodiment of the present invention, as shown in FIG. 1, a switching module 22 having a plurality of switching element (not shown), a condenser module 24 having a plurality of capacitors (not shown), and a DC power supply 19 for supplying an electric energy to each capacitor to charge each capacitor are disposed adjacent to the housing 15 in order that the heating source 16 can emit a pulsed light at a practical time interval.

The switching module 22 is electrically connected between the heating source 16 and the condenser module 24. The switching module 22 switches connections of the plurality of capacitors of the condenser module 24 to the heating source 16. The plurality of capacitors can be connected to the heating source 16, respectively, to supply electric charge for light emission to the heating source 16 independently. The switching module 22 is typically constructed by use of electrical switching elements, well-known power devices, such as power transistors and thyristors, and a control circuit. Under control of the switching module 22, one of the charged capacitors is connected to the heating source 16. The other capacitors are disconnected from the heating source 16 and charged by the DC power supply 19. When the heating source 16 completes to emit a light by use of the connected capacitor, one of the other charged capacitors is connected to the heating source 16 by switching, and the connected capacitor is used for another light emission. Efficient light emission can be achieved by switching the connections of the plurality of capacitors.

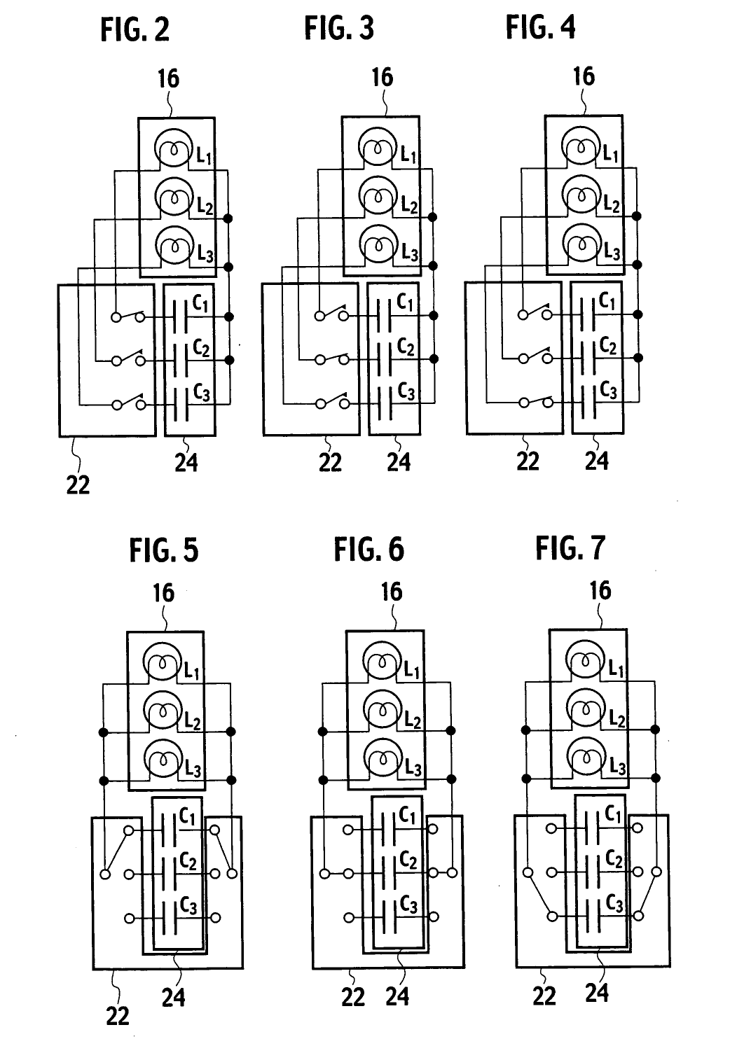

FIGS. 2 to 7 show exemplary configurations of the heating source 16, the switching module 22, and the condenser module 24 including the plurality of capacitors. For sake of simplicity, the number of capacitors is set to three, and the description of the DC power supply 19 is omitted. Actually, the number of capacitors is not limited to three but may be appropriately selected according to the intervals between light irradiations required of the heating source 16 or the amount of electric charge required for a single light emission.

FIGS. 2 to 4 show the exemplary configuration in which the heating source 16 includes a plurality of flashlamps L₁, L₂ and L₃ and capacitors C₁, C₂ and C₃ are assigned one by one to the flashlamps L₁, L₂ and L₃, respectively. In a single light emission, the capacitor C₁ is connected to the flashlamp L₁ so as to contribute to the emission of light from the flashlamp L₁ of the heating source 16, as shown in FIG. 2. During such situation, the other capacitors C₂ and C₃ are electrically disconnected from the heating source 16 and charged by the DC power supply. After completion of the light emission from the flashlamp L₁, the charged capacitor C₂ is connected to the flashlamp L₂, as shown in FIG. 3, so as to emit a light from the flashlamp L₂. Thereafter, the capacitor C₃ is connected to the flashlamp L₃, as shown in FIG. 4, so as to emit a light from the flashlamp L₃. Thus, the light emission is repeated from the heating source 16. A reduction in the practical process time, which is not feasible with a connection of a single capacitor to the flashlamp light source, is achieved by efficiently implementing the light emission and the charging of the remaining capacitors in the manner as above described.

An improved example of configuration, in which steeper increase and decrease in temperature in a shorter time is achieved, is shown in FIGS. 5 to 7. In the improved example, one capacitor Cᵢ (where i=1, 2, or 3) can be used to supply a sufficient amount of emission energy per pulse. Additionally, a smaller pulse width is set to yield higher light intensity in each pulse per unit time.

As shown in FIGS. 5 to 7, the numbers of the capacitors C₁, C₂ and C₃ and the flashlamps L₁, L₂ and L₃ are each set to three as in the case of the exemplary configuration shown in FIGS. 2 to 4. However, the flashlamps L₁, L₂ and L₃ in the heating source 16 are always connected in parallel, and each connection of the capacitors C₁, C₂ and C₃ to the heating source 16 is switched in sequence. For example, each configuration shown in FIGS. 5 to 7 is the same as each configuration shown in FIGS. 2 to 4 in that only one capacitor Cᵢ (where i=1, 2, or 3) connected to the heating source 16 contributes to the emission of light from the heating source 16, and the other capacitors Cⱼ (where j=1, 2, or 3, provided that j is not equal to i) are electrically disconnected from the heating source 16 and charged by the DC power supply 19 shown in FIG. 1. Since the flashlamps L₁, L₂ and L₃ connected in parallel are simultaneously turned on electricity; it is possible to emit a light with higher intensity in a shorter time. Since a pulse width and peak intensity of a pulsed light may be varied by using the exemplary configurations shown in FIGS. 5 to 7, as compared to the exemplary configurations shown in FIGS. 2 to 4, it is possible to select more proper conditions for dielectric film deposition according to the properties of the dielectric film and the substrate 10.

As described above, in the embodiment of the present invention, a plurality of capacitors, e.g., three capacitors C₁, C₂ and C₃, are arranged in parallel with each other. The capacitors C₁, C₂ and C₃ are simultaneously charged and alternately supply electric charges to the heating source 16. Thus, it is possible to irradiate pulsed lights from the heating source 16 at shorter intervals, which are about one third of intervals of the current flashlamp light source. From a standpoint of the productivity of a thin dielectric film, it is desirable to irradiate a pulsed light with one or more times every thirty seconds. It is desirable to ensure a deposition rate of at least about 5 nm per minute, in view of a practical deposition rate, while substantially maintaining deposition of a single atomic layer on each irradiation with a single pulsed light. Alternatively, it is desirable to ensure a deposition rate of at least about 1 nm per minute, in view of the practical productivity of a semiconductor device. Thus, a pulsed light from the heating source 16 is irradiated once every ten seconds, desirably once every five seconds, and more desirably once every one second. The number and capacitance of available capacitors are appropriately selected according to requirements as above mentioned.

As shown in FIG. 1, the operation of the switching module 22 as above described, in conjunction with the operations of the first and second gas introduction lines 17 and 27, is collectively executed by the control system 30.

As previously mentioned, in the deposition apparatus according to the embodiment of the present invention, thin dielectric film deposition is achieved by promoting a chemical reaction of the first gas and the second gas on the surface of the substrate 10 by energy originating from the irradiation of the surface of the substrate 10 with pulsed lights. The source gas is supplied from the first gas introduction line 17. The second gas contains one of the oxidizing agent, the reducing agent, and the nitriding agent is supplied from the second gas introduction line 27.

In order to make the best possible use of the features of a method of depositing a dielectric film according to the embodiment of the present invention, the control system 30 collectively controls the main operations of the deposition apparatus. The dielectric film deposition onto the substrate 10 is achieved by the sequential and repeated execution of cycles. Each cycle includes: introducing the first gas from the first gas introduction line 17; disconnecting the first gas from the first gas introduction line 17; evacuating the unreacted first gas by the evacuation system 18; introducing the second gas from the second gas introduction line 27; irradiating the pulsed light by the heating source 16; disconnecting the second gas from the second gas introduction line 27; and evacuating the unreacted second gas by the evacuation system 18. The pulsed light in each cycle is supplied by sequentially switching each connection of the plurality of capacitors to the heating source 16 coincident with the cycles. The capacitors, which are arranged in parallel with each other, are simultaneously charged during the cycles. Incidentally, the detailed description with regard to the features of a method for depositing a dielectric film according to the embodiment of the present invention will be given later. In the embodiment of the present invention, the irradiation of the pulsed light from the heating source 16 is achieved by the switching module 22 for switching connections of the capacitors to the heating source 16, as previously described. Specifically, the switching module 22 implements switching to provide an electrical connection between the heating source 16 and the charged capacitor Cᵢ (where i=1, 2, or 3) to emit the pulsed light. After the light emission, the switching module 22 implements switching to provide a connection between the heating source 16 and one of the other charged capacitor Cⱼ (where j=1, 2, or 3, provided that j is not equal to i).

With the configuration of the deposition apparatus as above described, a film deposition reaction is limited to occur on and near the surface of the substrate 10. Moreover, only a reacting species on the surface of the substrate 10 contributes to the film deposition reaction with a single irradiation of pulsed light. Thus, in the deposition apparatus according to the embodiment of the present invention, a thin dielectric film may be deposited with a low thermal budget, taking advantage of the flashlamp light while maintaining high controllability for a film deposition process and film quality. Moreover, the intervals between irradiations of the pulsed light can be responded by switching connections of the plurality of capacitors and also charging the capacitors during standby. Thus, it is possible to achieve a high temperature process in a short time using the flashlamp light at a practical deposition rate.

(Dielectric Film Deposition Method)

The description will be given below with regard to a method for depositing a dielectric film according to the embodiment of the present invention. The method includes depositing a dielectric film by an oxidation, reduction, or nitridation reaction using a compound containing a constituent element of the dielectric film to be grown, as the first gas, and one of an oxidizing agent, a reducing agent, and a nitriding agent, as the second gas. Desirably, the deposition apparatus shown in FIG. 1 may be used to practice the method.

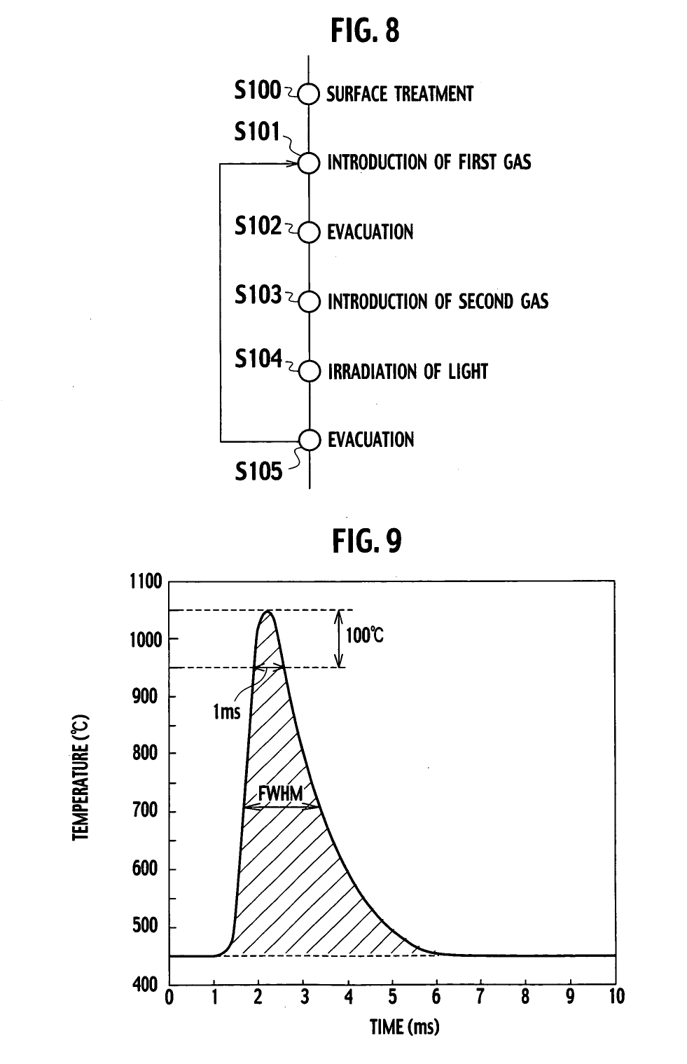

As shown in FIG. 8, the method includes repeating implementation after surface treatment of the substrate in Step S100, encompassing; introducing the first gas into the reaction chamber 11 in Step S101, evacuating the first gas in Step S102, introducing the second gas containing one of an oxidizing agent, a reducing agent, and a nitriding agent in Step S103, irradiating a pulsed energy such as flashlamp light in Step S104, and evacuating the second gas in Step S105.

As the compound containing the constituent element of the dielectric film and one of the oxidizing agent, the reducing agent, and the nitriding agent, compounds and agents currently used for depositing a dielectric film by CVD and the like, can be basically used. The compound containing the constituent element is typically a chloride, a hydride, an organic substance such as a hydrocarbon compound, or a combination thereof. The oxidizing agent, the reducing agent, or the nitriding agent is a chemical substance which can react with the compound containing the constituent element of the dielectric film at a high temperature to deposit a dielectric film. The oxidizing agent, the reducing agent, or the nitriding agent is desirably a gaseous substance.

An example of dielectric film deposition using the first and second gases includes deposition of a Si₃N₄ film using dichlorosilane (DCS) and NH₃, deposition of an SiO₂ film using DCS and nitrous oxide (N₂O), deposition of an SiO₂ film using silane (SiH₄) and N₂O, deposition of an alumina (Al₂O₃) film using trimethyl aluminum (Al(CH₃)₃) and ozone (O₃) or O₂, deposition of an Al₂O₃ film using Al(CH₃)₃ (TMA) and water (H₂O), and deposition of an Al₂O₃ film using dimethylethylamine-alane (DMEAA: (AlH₃)N(CH₃)₂C₂H₅) and O₃ or O₂. Further, other example of deposition includes deposition of a hafnium oxide (HfO₂) film using tetrakisdimethylaminohafnium (TDMAH: Hf(N(CH₃)₂)₄), tetrakis(ethylmethylamino)hafnium (TEMAH: Hf(NCH₃C₂H₅)₄), tetrakis(diethylamino)hafnium (TDEAH: Hf(N(C₂H₅)₂)₄) or hafnium chloride (HfCl₄), and O₃. In the examples, the deposition reaction of the Si₃N₄ film using DCS and NH₃ is particularly desirable. In addition, for the deposition of the Si₃N₄ film, hexachlorodisilane (HCD), trichlorosilane (TCS), or bis(tert-butylamino)silane (BTBAS) may be used as the compound containing the constituent element.

A method for depositing a dielectric film according to the embodiment of the present invention is basically feasible at a low pressure of about 1×10² Pa or a reduced pressure to an atmospheric pressure of about 1×10⁴ Pa to about 1×10⁵ Pa. Referring to FIG. 1, when depositing a dielectric film under a low or reduced pressure, the carrier gas introduction line 29 is basically held closed, except when operating in conjunction with the first or second gas introduction line 17 or 27 to supply mixed gas containing the carrier gas to the reaction chamber 11. The evacuation system 18 always operates to evacuate the reaction chamber 11. When depositing a dielectric film under an atmospheric pressure, the carrier gas introduction line 29 is basically always open to supply the carrier gas into the reaction chamber 11.

Descriptions will be provided for a method for depositing a dielectric film according to the embodiment of the present invention, using DCS and NH₃ as the first and second gas, with reference to the process flow shown in FIG. 8.

In Step S100, the substrate 10 is loaded on the susceptor 12. The substrate 10 is subjected to surface treatment. Specifically, the preheating source 20 is used to preheat the substrate 10, while the reaction chamber 11 is evacuated with supplying an inert gas, such as nitrogen (N₂) or argon (Ar), into the reaction chamber 11 through the carrier gas introduction line 29. Moisture, air components and the like adhered on the substrate 10 are removed by preheating.

In Step S101, after the surface treatment of the substrate 10, under a predetermined pressure, the valve V₁ of the first gas introduction line 17 is opened to introduce the first gas into the reaction chamber 11. For introducing the first gas, an inert gas such as N₂ or Ar is typically used as the carrier gas. The first gas mixed with the carrier gas is introduced into the reaction chamber 11. On this occasion, temperature of the substrate 10 is adjusted to a proper temperature by using the preheating source 20. Generally, the temperature of the surface of the substrate 10 is heated to between about 100° C. and about 700° C. throughout the process.

In Step S102, after an elapse of a predetermined gas residence time, the first gas in the reaction chamber 11 is evacuated. The valve V₁ in the first gas introduction line 17 is closed to disconnect the first gas. After disconnecting the first gas, the flow rate of the carrier gas supplied from the carrier gas introduction line 29 may be increased so as to intentionally purge the reaction chamber 11, in order to quickly evacuate the first gas remained in the reaction chamber 11.

In addition, progress and extent of the adsorption reaction of the reacting species are affected by a temperature of the substrate 10 on the occasion of the introduction of the first gas, a gas partial pressure of the compound containing the constituent elements in the reaction chamber 11, and a residence time of the compound on the surface of the substrate 10. For example, a lower gas pressure of the compound containing the constituent element in the reaction chamber 11 leads to a lower adhesion rate of compound molecules on the surface of the substrate 10. Thus, when setting a relatively lower gas partial pressure of the first gas in the reaction chamber, in general, it is necessary to increase correspondingly a residence time of the first gas on the surface of the substrate 10. An excessively higher gas pressure than a pressure required for Langmuir adsorption inhibits the desirable film deposition by a mono-atomic layer regime, resulting in a film deposition by a multi-atomic layer regime.

Additionally, depending on the dielectric film to be deposited and the compound to be used as the source material of the dielectric film, a more reactive activated species may be generated from the introduced compound molecules. The activated species may act as a precursor to contribute to the film deposition reaction. As a typical example, a film deposition may occur by a reaction path of dichlorosilicon (SiCl₂) decomposed as an adsorbed reacting species from DCS on the surface of the substrate 10. In such a situation, when the surface of the substrate 10 is not preheated above a specified temperature, generation of the adsorbed reacting species may be undesirably inhibited on the substrate 10. However, an excessive rise in the temperature leads to noticeable desorption of the adsorbed reacting species from the surface of the substrate 10. In any case, it is necessary to obtain proper empirical values for deposition conditions with an atomic layer regime by repeating investigation, so as to deposit a dielectric film under proper conditions.

In Step S103, after substantially evacuating the first gas from the reaction chamber 11, the valve V₂ of the second gas introduction line 27 is opened to introduce the second gas, such as the oxidizing agent, the reducing agent, or the nitriding agent, into the reaction chamber 11.

In Step S104, after introducing the second gas, a pulsed energy, such as pulsed light from the flashlamp light source, is applied to the surface of the substrate 10.

Although the pulsed light, as an energy for heating may be irradiated after evacuating the introduced second gas, typically, the energy is desirably applied while remaining the second gas in the reaction chamber 11. For example, one of the oxidizing agent, the reducing agent, and the nitriding agent is continuously introduced into the reaction chamber 11 with constant flow rate and partial pressure. Thus, the surface of the substrate 10 is irradiated with the pulsed light at the time when one of the oxidizing agent, the reducing agent, and the nitriding agent is introduced and remains as unreacted on the reacting species adsorbed on the surface of the substrate 10.

For example, in the case of the Si₃N₄ film to be described in further detail later, NH₃ molecules used as the nitriding agent tend not to adsorb on the surface of the substrate 10, as compared to the adsorbed reacting species generated from DCS. When the energy such as the flashlamp light is irradiated while NH₃ gas is continuously introduced into the reaction chamber 11, the energy serves to assist in adsorption of the NH₃ gas molecules on the surface of the substrate 10 in addition to chemical reduction of DCS thereon. Thus, it is very advantageous for depositing a dielectric film to irradiate the energy with introducing the second gas. If the energy is irradiated after one of the oxidizing agent, the reducing agent, and the nitriding agent gas is shut off and evacuated from the reaction chamber 11, the residence time of one of the oxidizing agent, the reducing agent, and the nitriding agent gas must be thoroughly preexamined as in the case of the introduction of the first gas.

Typically, the flashlamp light source used as the heating source 16 emits a light once, so as to irradiate the pulsed light on the surface of the substrate 10. In Step S105, after the irradiation, the second gas introduction line 27 is closed to disconnect the second gas to the reaction chamber 11. The carrier gas introduction line 29 and the evacuation system 18 operate to purge the reaction chamber 11. During evacuating the second gas, the unreacted oxidizing, reducing or nitriding agent on the top of the substrate 10 are removed.

As shown in FIG. 8, by repeating the above-described operations from Step S101 to Step S105, deposition is repeated desirably by an atomic layer regime. Accordingly, a dielectric film with a desired thickness is deposited on the substrate 10.

In the method according to the embodiment of the present invention, the energy required for the deposition reaction is supplied by irradiating the energy such as the flashlamp light onto the substrate 10. Thus, the film deposition reaction is limited to occurring on and near the surface of the substrate 10. Moreover, only the adsorbed reacting species which has not desorbed from the surface of the substrate 10 contributes to the film deposition reaction by irradiating a pulsed light. Thus, in the embodiment of the present invention, it is possible to deposit a dielectric film with a low thermal budget, using the advantages of the heating source 16, such as the flashlamp light, while maintaining high controllability for a film deposition process and film quality.

(Examination of Light Irradiation and Film Deposition Process)

As shown in FIG. 9, for example, a surface temperature of the Si semiconductor substrate 10 is changed with time in the case of a single irradiation of pulsed light from the flashlamp light source onto the surface of the substrate 10 at a preheating temperature of about 450° C.

A temperature profile of heating by the heating source 16 typically has a waveform exemplified in FIG. 9, in which the temperature sharply rises and falls as compared to an infrared lamp, such as a halogen lamp. Based on an analysis of a surface temperature of the silicon semiconductor substrate 10 by a high speed pyrometer or a simulation, temperature rising and falling time between about 500° C. and about 1050° C. (time that takes to return to 500° C. again after the temperature rises to 1050° C. from 500° C.), for the halogen lamp, is typically about ten s or more, for example, about fifteen s. Moreover, it typically takes about two s to about three s for the temperature rising or falling by about 100° C. between about 950° C. and about 1050° C. By contrast, for the flashlamp heating source 16, temperature rising and falling time between about 450° C. and about 1200° C., for example, can be adjusted to about 0.1 ms to about 200 ms, more desirably, about 0.5 ms to about 50 ms.

However, if drastically reducing a pulse width of the flashlamp light source by reducing an amount of electric charges of the condenser module 24 based on the emission principle of the flashlamp, a peak value of the flashlamp light is also decreased. As a result, an enough amount of energy applied to the substrate cannot be ensured. In other words, in the change of the surface temperature of the substrate 10 shown in FIG. 4, even if the pulse width of the heating source 16 is drastically reduced in order to achieve a rapid temperature rise or fall, pulse peak intensity is decreased at the same time. Thus, a sufficient peak temperature cannot be achieved. Moreover, a total amount of applied energy (approximately proportional to an area of the waveform shown in FIG. 9) also becomes insufficient. The exemplary configuration shown in FIGS. 5 to 7 provides a solution to the problem described above. Typically, if decreasing the temperature rising and falling time to about 0.1 ms or less, the maximum surface temperature of the Si semiconductor substrate 10 may be about 950° C. or less. If the temperature rising and falling time is increased to about 200 ms or more, in the case where the silicon semiconductor substrate 10 is used for manufacturing a semiconductor device including metal-oxide-semiconductor field effect transistors (MOSFETs), for example, there is a risk that already activated impurities in impurity diffusion layers of source and drain regions are inactivated again. Thus, in the case of thin dielectric film deposition as described above, the temperature rising and falling time of about 200 ms or more is undesirable.

In the embodiment of the present invention, the adsorbed reacting species generated from the source gas is adsorbed onto the surface of the substrate 10, and one of the oxidizing agent, the reducing agent, and the nitriding agent is introduced onto the adsorbed reacting species on the substrate 10. The surface of the substrate 10 and the surface layer below the surface of the substrate 10 are heated within a short period of time by irradiating with a pulse of the flashlamp light. The energy and one of the oxidizing agent, the reducing agent, and the nitriding agent advances decomposition of the adsorbed reacting species and a chemical oxidation, reduction, or nitridation reaction. As a result, a reaction product is deposited on the surface of the substrate 10 as a dielectric film. Only the reacting species, which is adsorbed on the surface of the substrate 10 and heated with the heating source 16, and one of the oxidizing agent, the reducing agent, and the nitriding agent, which is introduced onto the reacting species or remains on the top of the substrate 10, contribute to the deposition reaction. The progress of the deposition reaction is limited and controlled by the adsorbed reacting species. Chemical reactions in a vapor phase can be suppressed. Therefore, a high purity dielectric film can be obtained by several atomic layers regime, desirably, by a mono-atomic layer regime.

Furthermore, since heating process is implemented within a very short period of time, there is no harmful effect, such as inactivation and the like, even in the semiconductor device including the high-concentration impurity diffusion layers and the like which are likely to be inactivated by irradiating the energy. The flashlamp light has a main energy in a visible wavelength range. With regard to the substrate 10, such as a semiconductor substrate, the flashlamp light is relatively poorly absorbed as compared to an ultraviolet light having a small area, such as a laser. Thus, by using the flashlamp light, it is possible to minimize a thermal stress induced in the substrate 10.

In a current CVD method, both of the first and second gases are supplied at the same time. Thus, a reaction, which is desired substantially to occur only on the surface of the substrate 10, also occurs in the vapor phase, to contribute to deposition of a dielectric film. Moreover, a generation reaction of a film material tends to continuously progress along with simultaneously supplying both the first and second gases. For the above reasons, depending on the structure of the surface of the substrate 10 on which a dielectric film is deposited, there arise an area where film deposition is easy to occur, an area where film deposition is hard to occur, an area where film deposition tends to be inhibited, and the like. Accordingly, the film can not de deposited uniformly. Therefore, the current method has a problem such that step coverage is deteriorated in manufacturing of a semiconductor device having a minute structure.

In the embodiment of the present invention, the generation reaction of the film material is limited to occur on and near the surface of the substrate 10 to which the energy is applied by irradiation of the pulsed light. Moreover, a source material of the dielectric film is also limited to the number of molecules of the reacting species previously supplied and adsorbed onto the surface of the substrate 10 for every duration of introduction of the first and second gases, and pulsed light irradiation. Thus, the film deposition process can be similarly repeated over the entire exposed surface of the substrate 10 by several atomic layers regime or by a mono-atomic layer regime depending on the adsorption conditions over the entire surface of the substrate 10. Thus, it is possible significantly to contribute for the uniform film deposition including improvement of the step coverage.

As described above, in the embodiment of the present invention, various distinguished features are included all together. For example, the process of increasing and decreasing the temperature may be implemented in a short period of several ms, which can never be expected by use of the halogen lamp and the like. The properly poor absorption and conversion processes into the energy may be achieved by the flashlamp light, which are rather difficult to achieve by use of the ultraviolet light. The deposition reaction may use adsorption of molecules onto the substrate 10 and a portion of film deposition may be limited on the surface of the substrate 10. Controllability on reaction progress may be improved by separately introducing one of the oxidizing agent, the reducing agent, and the nitriding agent gas after an adsorption layer is formed. Thus, according to the embodiment of the present invention, it is possible to deposit a dielectric film having a good film quality with a low thermal budget.

Note that, as a method of alternately supplying gases so as to cause only the surface reaction, an atomic layer deposition (ALD) method and the like are heretofore proposed. Good step coverage can also be expected by ALD. However, in ALD, a film is generally deposited at a relatively low temperature in order to suppress reactions in the vapor phase, even though only a thermal reaction is used. Accordingly, ALD has a disadvantage that impurities such as carbon (C), for example, tend to remain in the deposited film. On the other hand, in the embodiment of the present invention, since decomposition on the surface of the substrate 10 is facilitated by the flashlamp light, the disadvantage of remaining impurities is resolved.

(Deposition of Si₃N₄ Film)

According to the embodiment of the present invention, a Si₃N₄ film can be deposited on the Si semiconductor substrate 10 by use of DCS and NH₃, and an entire reaction is as described in the following formula.
3SiH₂Cl₂+4NH₃→Si₃N₄+6HCl+6H₂

Although a deposition process can be performed with a reduced pressure, a low pressure or an atmospheric pressure, it is desirable that the deposition process is performed with the low pressure. Here, a carrier gas is constantly introduced from the carrier gas introduction line 29, and, at the same time, the evacuation system 18 is constantly driven to evacuate the reaction chamber 11, so as to perform the deposition process with the low pressure.

First, a native oxide film on the Si semiconductor substrate 10 is removed by wet processing. The substrate 10 is loaded on the susceptor 12. While supplying an inert gas, such as N₂ and Ar, from the carrier gas introduction line 29 into the reaction chamber 11, the substrate 10 is preheated by the preheating source 20 embedded in the susceptor 12, to purge moisture and air components which are attached to the substrate 10.

By the first gas introduction line 17, a DCS gas (first gas), which is a compound containing a constituent element of a dielectric film to be deposited, is introduced into the reaction chamber 11. A flow rate of the DCS gas is typically in a range of about one sccm to about 500 sccm. It is desirable that a total pressure of a mixture of the carrier gas and the DCS gas is in a range of about ten Pa to about 3000 Pa, and a partial pressure of the DCS gas in the mixture is in a range of about one Pa to about 100 Pa. It is desirable that a time for which the mixture is continuously introduced onto the surface of the substrate 10 with such a partial pressure, that is, a residence time is in a range of about one s to about 20 s. Within the range of the total pressure of the mixture, a vapor phase reaction, which can occur in a too high pressure, may be suppressed, and adhesion of the DCS gas mat be facilitated by setting to a moderate pressure. Within the range of the partial pressure of the DCS gas, uniform adhesion of the DCS gas may be facilitated. Within the range of the residence time of the DCS gas, required adhesion may be achieved.

Note that the DCS gas is introduced directly into the reaction chamber 11, and SiCl₂ molecules, which are more reactive than DCS molecules, are produced as reacting species. The SiCl₂ molecules contribute to deposition of the Si₃N₄ film together with the DCS molecules on the surface of the substrate 10. A particularly important parameter in order to facilitate generation of the adsorbed reacting species is a preheating temperature of the substrate 10. The preheating temperature of the substrate 10 is set higher within a range in which the adsorbed molecules do not substantially desorb. From this perspective, a desirable range of the preheating temperature (the surface temperature of the substrate 10) may be about 350° C. to about 600° C.

When depositing a Si₃N₄ film on the substrate 10, such as Si semiconductor substrate, as a manufacturing process for a semiconductor device, it is necessary to consider problems such as a defect induced in the substrate 10 with irradiation of the flashlamp light, and inactivation of impurity atoms in the impurity diffusion layers. From this viewpoint, a desirable preheating temperature of the substrate 10 is in a range of about 200° C. to about 550° C. If the preheating temperature is less than 200° C., it is necessary significantly to increase pulsed energy of the flashlamp light in order to deposit a dielectric film by decomposing the compound containing the constituent element and advancing a reduction reaction using the NH₃ gas. Thus, a crystal defect may be generated in the semiconductor substrate 10. On the other hand, if preheating is implemented at the temperature exceeding about 550° C., impurity atoms in the impurity diffusion layers already formed on the substrate 10 may be inactivated. Therefore, from a comprehensive standpoint, the range of about 200° C. to about 550° C. is the desirable preheating temperature range.

After an elapse of the residence time of the DCS gas, the first gas introduction line 17 is closed to disconnect the DCS gas. Furthermore, while preheating the substrate 10, an undiluted NH₃ gas (second gas) is introduced into the reaction chamber 11 from the second gas introduction line 27. A flow rate of the NH₃ gas is typically about ten sccm to about 1000 sccm. It is desirable that a partial pressure of the NH₃ gas inside the reaction chamber 11 is in a range of about 100 Pa to about 30000 Pa. This is because the range described above is an optimum condition in order to sufficiently adhere nitrogen atoms onto the reacting species generated in the previous step.

It is desirable that irradiation of the pulsed light from the flashlamp light source is implemented while maintaining the NH₃ gas partial pressure after an elapse of a residence time of the NH₃ gas, desirably, after about 0.5 s to about 20 s. Regarding the reacting species from the DCS gas, adsorption may easily occur only by flowing the DCS gas onto the surface of the substrate 10. However, in the case of the NH₃ gas, since adsorption does not progress as much as that in the case of the DCS, the irradiation of the flashlamp light assists performance of adsorption of the NH₃ gas. Thus, it is possible to facilitate a deposition reaction of the Si₃N₄ film on the surface of the substrate 10. While remaining the NH₃ gas in the reaction chamber 11, the surface of the substrate 10 is heated to the peak temperature of about 1050° C. by the heating source 16, so as to deposit the Si₃N₄ film on the surface of the Si substrate 10.

A typical temperature rising and falling time of the surface of the substrate 10 is about 5 ms between about 450° C. and about 1050° C., and it takes about 1 ms, for example, for the temperature to rise and fall by a temperature of about 100° C. between about 950° C. and about 1050° C. Accordingly, an energy of the pulsed light per unit area of the substrate 10 is desirably in a range of about 20 J/cm² to about 30 J/cm².

In the case of a rapid thermal process (RTA) using an infrared lamp, such as the halogen lamp, time for the temperature to rise and fall ms between about 450° C. and about 1050° C., is about several seconds to several ten seconds. Moreover, if impurity atoms, such as boron (B) and phosphorus (P), are included in the Si semiconductor substrate, although depending on the temperature of the substrate at the time, in the case where the temperature is about 1000° C., for example, it is possible to estimate that time for the impurity atoms to diffuse into several atomic layers, for example, into about one nm is in the order of about 10⁻¹ s.

Therefore, in a high temperature process using the flashlamp light with the temperature rising and falling time of millisecond (ms) order, that is, in the method of depositing a Si₃N₄ film according to the embodiment of the present invention, it is possible to significantly prevent the problem of inactivation of the impurity atoms in the Si₃N₄ film deposition process. In other words, it is understood that a significantly reduced thermal budget can be achieved. Influences of the deposition process, which will be also described below, are examined by depositing a Si₃N₄ film after forming the impurity diffusion layers, based on changes in resistance values of the impurity diffusion layers. Results also support the validity of the speculations described above.

(First Deposition Example—Si₃N₄ Film)

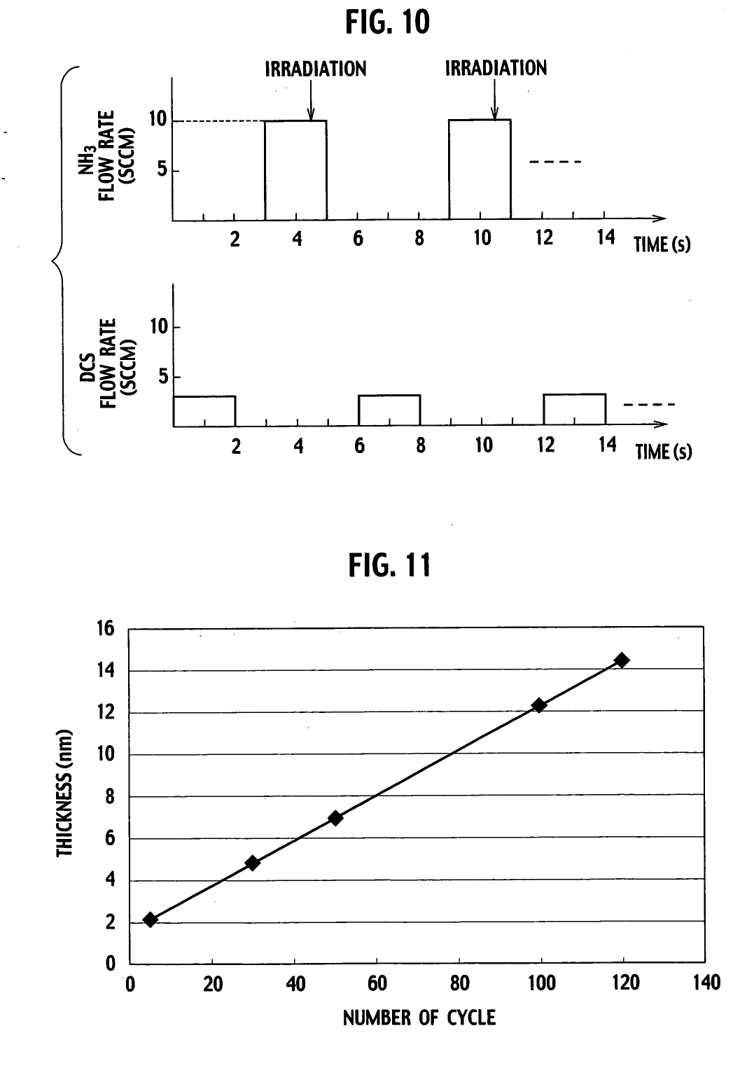

Deposition of the Si₃N₄ film is performed with the following conditions. FIG. 10 shows timing charts of the deposition process by focusing on changes of flow rates of DCS and NH₃ gases in the reaction chamber 11 and timing of light irradiation.

A N₂ gas is used as a carrier gas, and the DCS gas is introduced into the reaction chamber 11 with a flow rate of about three sccm. A total pressure inside the reaction chamber 11 by a mixture of the carrier gas and the DCS gas is about 400 Pa. A partial pressure of the DCS gas is about 130 Pa. A contact time with the surface of the substrate 10, that is, a supply time of the DCS gas is about two s. Thereafter, the DCS gas is disconnected, and substantially 100% NH₃ gas is immediately introduced into the reaction chamber 11. A flow rate of the NH₃ gas is about ten sccm, and a partial pressure of the NH₃ gas is about 3000 Pa. At an elapse of about 1.5 s after the supply of the NH₃ gas has been started, the surface of the substrate 10 is irradiated with one shot of pulsed light from the flashlamp light source having a pulse width of about 1 ms and an energy density on the surface of the substrate 10 of about 20 J/cm² to about 30 J/cm² while continuing the supply of the NH₃ gas.

After the irradiation of the pulsed light, the NH₃ gas is disconnected. The reaction chamber 11 is evacuated by the evacuation system 18. Thereafter, the step described above is repeated. For repetitive emissions of the flashlamp light source, three capacitors, each having capacitance of about 600 μF, are used. These capacitors are alternately used for the respective emissions. Note that, during the process, the preheating source 20 is constantly operated with a fixed output so as to heat the surface temperature of the substrate 10 between about 400° C. and 550° C. without irradiation of the pulsed light.

After the film deposition is finished, the substrate 10 is taken out of the reaction chamber 11, and the deposited film on the surface of the substrate 10 is investigated by Auger electron spectroscopy (AES) and the like. As a result, deposition of a Si₃N₄ film is determined since Si and N atoms are detected at a ratio of about 3.1:4.

As shown in FIG. 11, thickness of the Si₃N₄ film increases along with a number of cycles of deposition. Here, a “cycle” is defined as the operations from Step S101 to Step S105 shown in FIG. 8. For example, when an interval between irradiations is about six s, it takes about five min to repeat 50 cycles. As a result, the Si₃N₄ film having a thickness of about seven nm is deposited. Therefore, a deposition rate is about 1.4 nm/min or about 0.14 nm/pulse. Thus, it is understood that the Si₃N₄ film can be deposited by a mono-atomic layer regime for every single pulsed light irradiation.

As a film quality evaluation of the deposited Si₃N₄ film, hydrogen concentration in the film is measured by secondary ion mass spectrometry (SIMS). As a result, the hydrogen concentration of about 1×10¹⁹ cm⁻³ or less is confirmed. The value of the hydrogen concentration is reduced by a few tenths of a Si₃N₄ film deposited by a current thermal CVD method in which a substrate temperature is about 780° C. Thus, according to the embodiment of the present invention, a high-purity Si₃N₄ film can be deposited on the Si semiconductor substrate at a low thermal budget.

As a comparative example, a Si₃N₄ film is deposited on the Si semiconductor substrate 10 in such a manner that the DCS and NH₃ gases are simultaneously introduced into the reaction chamber 11, and the surface of the substrate 10 is continuously irradiated with the pulsed light of the flashlamp light source more than once while maintaining flow rates of the repective gases.

The setting values of flow rates of the DCS and the NH₃ gases are three sccm and ten sccm, respectively. A total pressure inside the reaction chamber during pulsed light irradiation is about 20 Pa. Partial pressures of DCS and NH₃ are about three Pa and about ten Pa, respectively. The pulse width, the energy density, the preheating temperature of the substrate 10, and the like are the same values as already described in the explanation of the embodiment of the present invention.

By evaluating the quality of the deposited film of the comparative example, deposition of a Si₃N₄ film is confirmed. The Si₃N₄ film having a thickness of about 40 nm is obtained by 50 times of irradiation of the pulsed light. Thus, deposition of the Si₃N₄ film by an average thickness of 0.8 nm per pulsed light irradiation is confirmed. Moreover, based on the analysis by SIMS, a hydrogen atom concentration in the Si₃N₄ film of the comparative example is about 1×10²⁰ cm⁻³ or less.

Therefore, it is understood that a dielectric film can be also deposited with continuous irradiation of the pulsed light from the flashlamp light source while simultaneously supplying the DCS and the NH₃ gases into the reaction chamber 11. However, in such case, the deposition apparently occurs by a multi-atomic layer regime. Thus, there is a problem of controllability in the film deposition process, such as uniformity of the film. Moreover, the hydrogen content in the deposited film of the comparative example is larger by about one digit than that of the embodiment of the present invention. Thus, film quality of the film of the comparative example is also inferior to the embodiment of the present invention. However, there is no significant difference in the hydrogen content in the Si₃N₄ film between the comparative example and the current thermal CVD method.

(Second Deposition Example—Al₂O₃ Film)

An Al₂O₃ film is deposited on the surface of the Si semiconductor substrate 10 by using TMA as a compound containing a constituent element and O₂ as an oxidizing agent gas. A deposition method is similar to that used in the deposition example of the Si₃N₄ film. Specifically, a first gas containing TMA and the oxidizing agent gas (second gas) are alternately supplied, and a flashlamp light is irradiated in the duration of introduction of the second gas with maintaining a constant flow rate.

N₂ is used as a carrier gas. The first gas is introduced with a flow rate of about ten sccm. A total pressure of the first gas containing the carrier gas is about 80 Pa inside the reaction chamber 11. A partial pressure of TMA is about 30 Pa. A supply time of TMA molecules to the surface of the substrate 10 is about one s.

The second gas is introduced with a flow rate of about 100 sccm. A total pressure of the second gas is about 300 Pa inside the reaction chamber 11. At an elapse of about 1.5 s after supply of the second gas is started, the surface of the substrate 10 is irradiated with one shot of pulsed light from the flashlamp light source, as the heating source 16, having a pulse width of about three ms and an energy density of about ten J/cm² on the surface of the substrate 10.

For repetitive emissions of the flashlamp light source, three capacitors are prepared in the condenser module 24. Each capacitor including three capacitor elements has an effective capacitance of about 600 μF. Each of the capacitor elements, which are connected in parallel, has a capacitance of about 200 μF. The capacitors are alternately used for respective emissions. An interval between emissions is about six s. It takes about eight min to repeat 80 cycles. For 80 cycles, a thickness of the deposited film is about 9.6 nm. Therefore, a deposition rate is about 1.2 nm/min or 0.12 nm/pulse. Note that the preheating temperature of the surface of the substrate 10 is constantly maintained at about 600° C.

By evaluating the quality of the deposited film by Rutherford backscattering spectrometry (RBS), deposition of an Al₂O₃ film is confirmed. Additionally, carbon (C) concentration in the film is analyzed by SIMS. As a result, the C concentration of about 1×10¹⁹/cm³ or less in the Al₂O₃ film is obtained.

(Third Deposition Example—For Semiconductor Device)

When a Si₃N₄ film is deposited for forming a gate insulating film and the like after shallow diffusion layers are formed on the silicon semiconductor substrate 10, advantages of implementing a method for depositing a Si₃N₄ film according to the embodiment of the present invention will be verified.

As a typical example of ion implantation of impurity for a recent high density integrated circuit (IC) using a lot of metal-insulator-semiconductor (MIS) structures, will be described. An impurity ion species, such as a B ion (B⁺), is implanted into the Si semiconductor substrate 10. Ion implantation conditions are an acceleration energy of about 1.5 keV and an implant dose of 1×10¹⁵ cm⁻², for example. Further, the implanted surface of the substrate 10 is annealed by flashlamp annealing. Flashlamp annealing conditions are a pulse width of about eight ms, an irradiation energy density of about three J/cm², and a number of irradiation shots of three. Accordingly, impurity diffusion layers in source and drain regions of the MIS structure are formed. A depth of each impurity diffusion layer is about 15 nm from the surface of the substrate 10.

By use of the substrate 10 described above, a Si₃N₄ film according to the first deposition example is further deposited on the surface of the substrate 10. A thickness of the Si₃N₄ film is about 20 nm. Time for depositing the Si₃N₄ film is about 30 min. As a comparison, a comparative substrate, on which a Si₃N₄ film is deposited at about 780° C. for 30 min, is also prepared by current thermal CVD using a batch processing apparatus, which uses the same source material gases.

For each of the substrates, after deposition of the Si₃N₄ film, sheet resistance of each impurity diffusion layer is measured. For example, sheet resistance of the impurity diffusion layer in the substrate 10 according to the embodiment of the present invention is about 820 Ω/sq. Sheet resistance of the impurity diffusion layer in the comparative substrate is about 1200 Ω/sq. Note that sheet resistance of the impurity diffusion layer before depositing the Si₃N₄ film is about 800 Ω/sq.

From the result described above, it is understood that, if the Si₃N₄ film is deposited by the method according to the embodiment of the present invention after the impurity diffusion layers are formed on the substrate 10, occurrence of adverse effects such as inactivation of the impurities in the underlying impurity diffusion layers can be significantly suppressed while ensuring film deposition with a low thermal budget by use of the flashlamp light.

### OTHER EMBODIMENTS

The present invention has been described above by taking up the specific embodiment. However, the present invention may include various embodiments and the like, which are not described here. For example, decrease of a thermal budget largely depends on absorption efficiency of a pulsed light on a surface of a substrate, and a rate of conversion into heat energy. By changing a wavelength of a pulsed light so as to increase absorption more effectively, a high temperature process in a short period of time may be more easily achieved. However, the increase of absorption causes a problem due to particularly local energy application, such as stress generated in the substrate and deterioration due to the stress. Adversely, by use of the flashlamp light, it is possible to obtain a wavelength region, a pulse width, and an energy strength, which can provide an approximately appropriate absorption process, in order to achieve a high temperature process in a short period of time explained in the embodiment of the present invention. Thus, absorption rate and efficiency of applied energy from the flashlamp light can be actively further optimized and refined by engineers. From this viewpoint, depending on the type of the dielectric film to be formed or the type of the substrate, the heating source can be further modified and improved within the scope of the present invention.

Various modifications will become possible for those skilled in the art after storing the teachings of the present disclosure without departing from the scope thereof.

What is claimed is:

1. An apparatus for depositing a dielectric film, comprising:
a first gas introduction line configured to introduce and disconnect a first gas to a surface of a substrate stored in a reaction chamber, the first gas including a compound containing a constituent element of the dielectric film;
a second gas introduction line configured to introduce and disconnect a second gas to the surface of the substrate, the second gas containing one of an oxidizing agent, a reducing agent, and a nitriding agent;
a heating source configured to repeatedly irradiate a pulsed energy on the substrate to heat the substrate, the energy having a pulse width of about 0.1 ms to about 100 ms;
an evacuation system configured to evacuate the first and second gases from the reaction chamber; and
a control system configured to sequentially and repeatedly execute a cycle, the cycle including operations of introducing the first gas, disconnecting the first gas, evacuating the unreacted first gas, introducing the second gas, irradiating the energy, disconnecting the second gas, and evacuating the unreacted second gas.

2. The apparatus of claim 1, wherein the heating source is a flashlamp light source.

3. The apparatus of claim 1, wherein the energy has an energy density in a range of about 5 J/cm² to about 100 J/cm².

4. The apparatus of claim 1, further comprising a preheating source configured to preheat the substrate.

5. The apparatus of claim 1, wherein the constituent element is one of silicon, aluminum, and hafnium.

6. The apparatus of claim 1, wherein the second gas is one of ammonia, nitrous oxide, ozone, oxygen, and water.

7. The apparatus of claim 2, wherein the flashlamp light source includes a plurality of flashlamps.

8. The apparatus of claim 2, wherein the flashlamp light source is connected to a plurality of capacitors which feed an electric charge for light emission, through a plurality of switching elements.

9. The apparatus of claim 4, wherein the substrate is preheated in a temperature range of about 100° C. to about 700° C.

10. A method for depositing a dielectric film, comprising sequentially and repeatedly executing a plurality of cycles, each of the cycle including:
introducing a first gas including a compound containing a constituent element of the dielectric film, so as to adsorb reacting species on a surface of a substrate, the reacting species being molecules of the first gas or decomposed molecules of the first gas;
introducing the second gas containing one of an oxidizing agent, a reducing agent, and a nitriding agent to the surface of the substrate; and
irradiating a pulsed energy having a pulse width of about 0.1 ms to about 100 ms on the surface of the substrate, so as to react the second gas to the adsorbed reacting species.

11. The method of claim 10, wherein the energy is achieved by a flashlamp light.

12. The method of claim 10, wherein the second gas is introduced on top of the adsorbed reacting species, and the energy is irradiated when the second gas remains as unreacted on the adsorbed reacting species.

13. The method of claim 10, further comprising evacuating the unreacted first gas after adsorbing the reacting species.

14. The method of claim 10, further comprising evacuating the unreacted second gas after irradiating the energy.

15. The method of claim 10, wherein the energy has an energy density in a range of about 5 J/cm² to about 100 J/cm².

16. The method of claim 10, wherein the substrate is preheated in a temperature range of about 100° C. to about 700° C.

17. The method of claim 10, wherein the constituent element is one of silicon, aluminum, and hafnium.

18. The method of claim 10, wherein the second gas is one of ammonia, nitrous oxide, ozone, oxygen, and water.

19. The method of claim 11, wherein a pulsed energy of the flashlamp light in each of the cycles is supplied by sequentially switching each connection of a plurality of capacitors to the flashlamp coincident with the cycles, the capacitors arranged in parallel with each other being simultaneously charged during the cycles.
